(19) United States
(12) Patent Application Publication
(10) Pub. No.: US 2010/0273387 A1
(43) Pub. Date: Oct. 28, 2010

(54) Processing Apparatus and Method of Manufacturing Electron Emission Element and Organic EL Display

(75) Inventors: Masato Inoue, Kawasaki-shi (JP); Shin Matsui, Kawasaki-shi (JP); Toshiaki Himeji, Kawasaki-shi (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi, Kanagawa (JP)

(21) Appl. No.: 12/809,209

(22) PCT Filed: Dec. 26, 2008
(86) PCT No.: PCT/JP2008/073704

§ 371 Date: Jun. 18, 2010

(30) Foreign Application Priority Data
Dec. 27, 2007 (JP) 2007-336693

(51) Int. Cl. H01J 9/00

(52) U.S. Cl. 445/58; 445/60

(57) ABSTRACT

Disclosed is a processing apparatus which can realize highly fine batch pattern film formation for a mask, which is significantly increased in weight according to the demand for increasing the size of an object to be processed, whereby leading to a possibility of reduction in the alignment accuracy of a pattern.

The processing apparatus 1 which fixes and processes an object to be processed 300 and a mask 200 includes a base 400 on which the object to be processed 300 and the mask 200 are placed. The processing apparatus 1 further includes second fixing means 101 and first fixing means 102. The second fixing means 101 includes a permanent magnet for use in fixing a mask frame 200a of the mask 200 on the base 400. The first fixing means 102 includes a permanent magnet for use in fixing a mask membranous plane 200b of the Mask 200 on the base 400. The second fixing means 101 and the first fixing means 102a, 102b are mechanisms in which each permanent magnet can move the base 400 in a vertical direction.

### TECHNICAL FIELD

This invention relates to a processing apparatus, which adheres and fixes a mask to an object subjected to processing such as film formation and forms a desired pattern on the surface of the object other than an area covered by the mask, and a method of manufacturing an electron emission element and an organic EL display using the processing apparatus.

### BACKGROUND ART

An apparatus for manufacturing an image display apparatus includes, as an example, a glass substrate manufacturing apparatus for a flat panel display typified by an organic electroluminescence element. With regard to such a substrate for a display, in general, a desired pattern is formed on the substrate with desired accuracy, whereby desired functions are imparted to the substrate.

As a pattern formation method, there have been known a vacuum deposition method, a sputtering method, a photolithography method, and a screen printing method. However, at present, a display is required to have a higher-definition display performance. Thus, a pattern formation apparatus is required to have more highly fine pattern formation accuracy.

As shown in Patent Document 1, the vacuum deposition method, as with the sputtering method, has been known as a method that can realize a highly fine pattern at low cost and with high reliability, in comparison with other methods.

In particular, in the production of a display using an organic electroluminescence element as a display element, the vacuum deposition method has attracted attention as a dry process that causes very few moisture damages on an element that may occur in a wet process typified by photolithography.

For example, in the pattern film formation by means of vacuum evaporation, in such a state that a mask is adhered to a surface of a substrate as an object to be processed, a material is deposited through the opening of the mask previously formed in the pattern portion, whereby a desired pattern is formed on the substrate.

In the vacuum evaporation, the finishing accuracy of a mask directly depends on the finishing accuracy of the pattern, and therefore, means for forming a minute pattern on a mask with high accuracy is required to be developed (for example, see, Patent Document 2).

In the formation of a minute pattern on a mask, the thickness of the mask should be reduced, and, at the same time, for the purpose of ensuring adherence with an object to be processed and the pattern accuracy as a mask, the mask is required to have such flatness that deflection and creases of the mask are prevented from occurring.

Based on the above purpose, there has been known a method shown in Patent Document 3. In this method, a metal mask with a thickness of not more than 500 μm is fixed to a frame while tension is applied to the mask.

The metal mask has such a constitution that the outer peripheral edge of the mask is welded together with a frame by application of tension, and therefore, if tension is always applied to the mask, the reaction force is always applied to the frame at the same time. Consequently, although the flatness of the mask is ensured, the frame is required to have a high rigidity.

This is because the reaction force against the tension applied to the mask is required to be ensured by the rigidity of the frame. If the rigidity of the frame is small, the frame itself is deformed by the reaction force, and the tension is relieved, whereby predetermined accuracy cannot be maintained.

Based on the above reasons, in order to realize minute pattern accuracy, the frame of the mask is required to have a high rigidity, which means the increase of the weight of the metal mask.

The multi-piece molding based on the request for the improvement of the processing performance and the increase of the size of an object to be processed itself cause the increase of the size and weight of a mask. For example, there is a metal mask for 55 inch size (about 130×800 mm) having a weight of 300 kg.

When the size and weight of a mask are increased, a mechanism that aligns the position of the mask with an object to be processed and a mechanism that moves the mask are increased in size, whereby it is difficult for a film formation apparatus to maintain high accuracy.

Thus, the film formation apparatus is required to include means that can be simply handled while high accuracy is maintained even when a heavy mask is used.

In addition, in a film formation process in a vacuum deposition method, a pattern formation surface of an object to be processed is required to be directed downward, generally called face-down (deposition-up), so as to face an evaporation source.

In the process for aligning a position of an object to be processed with a mask, in general, the mask and/or the object to be processed is slightly moved in such a state that they are placed on a base having flatness with fixed accuracy.

When the process from the positional alignment to the film formation is considered, there is required means for maintaining the positions of the mask and the object aligned with each other even in a state of being turned upside down, without causing positional deviation.

Based on the above, in addition to correspondence to the increase in size of an object to be processed, and, in order to ensure highly fine pattern accuracy, means for fixing a mask is required to hold and fix a mask significantly increased in weight, without causing positional deviation. Further, for the same purposes, the mask fixing means is required to ensure adhesion between the mask and the object to be processed.

As a conventional technique for realizing the above requirements, Patent Document 4 proposes such means that, for example, in a multi-piece molding device, an area is divided into small size, and a mask is arranged on the divisional areas, or a deposition process is applied thereto, whereby the weight of the mask can be reduced while high positional alignment accuracy is ensured.

FIG. 6 shows a schematic configuration example of the technique disclosed in Patent Document 4. In the deposition apparatus shown in FIG. 6, a mask alignment mechanism 212 aligns the positions of a plurality of masks having the same pattern on a substrate placed on one substrate base 211. After the positional alignment of each mask, the substrate base 211 fixed with the masks and the substrate is reversed to a face down attitude in a substrate reverse part 220. The substrate in the face down attitude is evaporated from an evaporation source 231 in a vacuum chamber 240 by a film formation part 230.

As the fixing means for a mask and an object to be processed, a magnet is used for fixing a metal mask which is a magnetic body; however, a necessary fixing force is increased as the weight of the mask is increased, whereby damage caused by contact between the mask and the object to be processed and positional deviation caused by impact may occur.

In order to prevent the occurrence of damage and positional deviation in the fixing of a mask through a magnet, Patent Document 5 proposes that an object to be processed and a mask are formed of a semiconductor material with high flatness such as silicon, and an electrostatic chuck is used in the means that fixes the object to be processed and the mask.

FIG. 7 shows a configuration example of a deposition apparatus using the above technique. In the deposition apparatus, deposition masks 302 aligned by using cameras 303A and 303B are firmly fixed to a glass substrate 320, and the glass substrate 320 is directed downward, that is, put in the face down attitude so as to face a crucible 361 which is a deposition source. In this technique, a voltage is applied to electrodes 301A embedded in a stage 301 so that the stage 301 serves as an electrostatic chuck, whereby the glass substrate 320 is fixed to the stage 301. The deposition mask 302 is formed of a silicon material with high flatness and held by holders 330 having a different structure. Thus, the positional deviation caused by damage or impact does not occur, unlike the fixing using a magnet.

Even when tension is applied to a mask membranous plane (membrane) of a mask, which is a portion having a desired pattern opening, the mask membranous plane has a slight deflection, and thus there exists a difference in the flatness of the mask relative to the rigidity of an object to be processed.

Therefore, when the mask and an object to be processed are in contact with each other, the adherence therebetween decreases, resulting in creases of the mask. Consequently, when a gap is generated between the contact surfaces between them, a deposition material infiltrates a place other than the opening of the mask, leading to the reduction of the finishing accuracy of the pattern of the mask.

The reduction of the pattern accuracy is called “film-formation blur”. In order to prevent the film-formation blur, the adhesion between a mask and an object to be processed is required to be enhanced as much as possible.

As a conventional technique for realizing the above requirement, Patent Document 6 proposes a method of fixing a mask and an object to be processed in sequence from one side end of the mask toward the other opposite side end, whereby the adhesion area between the mask and the substrate is increased.

FIG. 8 is a cross-sectional view showing the mask fixing process using the method disclosed in Patent Document 6. As shown in FIG. 8, a metal mask 402 and a substrate 401 are disposed in parallel, and then a plate-like magnet 403 for ensuring the adhesion between the metal mask 402 and the substrate 401 is disposed on a surface of the substrate 401 remote from the metal mask 402. The plate-like magnet 403 is brought into contact with the substrate 401 in sequence from one side end of the substrate 401 toward the other side end, whereby the metal mask 402 and the substrate 401 are adhered to each other without causing creases of the metal mask 402.

### [Patent Document 1] Japanese Patent Application Laid-Open No. 6-51905

### [Patent Document 2] Japanese Patent Application Laid-Open No. 10-41069

### [Patent Document 3] Japanese Patent NO. 3539125

### [Patent Document 4] Japanese Patent Application Laid-Open No. 2003-73804

### [Patent Document 5] Japanese Patent Application Laid-Open No. 2004-183044

### [Patent Document 6] Japanese Patent Application Laid-Open No. 2004-152704

### DISCLOSURE OF THE INVENTION

### Problems to be Solved by the Invention

However, in the divided deposition method shown in Patent Document 4 and using small-sized masks disposed in each divided processing region, there is a problem that it takes time to align the positions of the masks, resulting in the increase of the device tact time. Further, there is also a problem that the divided deposition method cannot easily correspond to the increase in size of a substrate, on which a large number of the same patterns are deposited all together for the sake of the multi-piece molding.

Meanwhile, the means that fixes an object to be processed using the electrostatic chuck disclosed in Patent Document 5 has the following problem.

When the object to be processed is a glass, the glass which is an insulator has a high volume resistivity, and thus a satisfactory electrostatic adsorption power is not generated under normal temperature condition. Thus, in order to decrease the volume resistivity, the procedure of rising and falling temperature and the addition of a heating mechanism are required for a film formation apparatus. Alternatively, the film formation apparatus requires a new process of applying a conductive film onto the glass so that the glass is rendered electrostatically adsorbable.

Thus, when a film is formed on a glass, an additional measure is required, and consequently, there arises a new problem of causing increase in a tact time and costs of the apparatus.

The procedure for increasing the adhesion between the mask and the object to be processed, disclosed in Patent Document 6 has such a problem that, because the mask and the object to be processed are always fixed in sequence from one side end, the degree of freedom upon change in the size of the object to be processed is limited.

Especially when a large-sized substrate will be processed, there occurs such a problem that the degree of design freedom and expandability of a processing apparatus are limited.

It is thus an object of the present invention to provide a processing apparatus which can solve the above problems of the prior arts. Especially, the processing apparatus can solve the problems of the prior art assuming that a mask used in the apparatus is formed of a magnetic material in a thin film form, and tension is applied to a membranous plane of the mask.

One object of the present invention is to realize highly accurate batch pattern film formation for a mask, which is significantly increased in size according to the demand for increasing the size of an object to be processed and thereby has a concern that the pattern accuracy is reduced. Another object is to provide an apparatus and a method that can prevent the occurrence of damage and positional deviation in the fixing of a mask without using a component such as an electrostatic chuck. A further object is to provide an apparatus, which can easily correspond to the demand for increasing the size of an object to be processed and has a high expandability, and a method of manufacturing a display using the apparatus.

### Means for Resolving the Problems

One embodiment of the present invention relates to a processing apparatus that processes an object to be processed by using a mask mechanism having a magnetic mask member and a magnetic mask frame fixing the periphery of the magnetic mask member. In order to solve the above problems, the processing apparatus is characterized by including a plurality of first fixing means and second fixing means. The first fixing means fix the magnetic mask member and can each independently operate. The second fixing means operates independently from the first fixing means and fixes the magnetic mask frame.

Another embodiment of the present invention relates to a method of manufacturing an electron emission element and an organic EL element that is characterized by comprising a step of processing an object to be processed, using the processing apparatus of the above embodiment.

### EFFECTS OF THE INVENTION

According to the present invention, even when a mask, which corresponds to the demand for increasing the size of an object to be processed, is used, the highly accurate batch pattern film formation can be realized, and, at the same time, the object to be processed can be prevented from being damaged. Further, it is possible to easily correspond to the demand for increasing the size of the object to be processed.

### BRIEF DESCRIPTION OF THE DRAWINGS

FIG. 1 is a schematic view of a processing apparatus which is one embodiment of the present invention;

FIG. 2 is a view showing a mask fixing operation from positional alignment of a mask to preparation of deposition in the processing apparatus of the present invention;

FIG. 3 is a perspective view showing a structure of an electron emission element display manufactured using the processing apparatus of the present invention;

FIG. 4 is a schematic view showing a cross-sectional structure of an organic EL display manufactured using the processing apparatus of the present invention;

FIG. 5 is a flow chart showing a general method of manufacturing a light-emitting part of the organic EL display;

FIG. 6 is a perspective view showing a schematic configuration of a film formation apparatus disclosed in Patent Document 4;

FIG. 7 is a front view showing a schematic configuration of a film formation apparatus disclosed in Patent Document 5; and

FIG. 8 is a view showing a state that a magnet for fixing a mask to a substrate is disposed in a film formation apparatus disclosed in Patent Document 6.

### DESCRIPTION OF REFERENCE NUMERALS

1 Processing apparatus
101 Second fixing means (permanent magnet)
102 First fixing means (permanent magnet)
102a Group comprising fixing means for fixing central portion of mask membranous plane
102b Group comprising fixing means for fixing peripheral portion of mask membranous plane
103, 103a, 103b Hole
104 Driving mechanism for first fixing means
105 Control means
106 Driving mechanism for second fixing means
107 Gate valve
108 Evacuation tube
109 Evacuation means
111 Vessel
200 Mask
200a Mask frame
200b Mask member (mask membranous plane)
300 Object to be processed (glass substrate)
400 Base
501 Electron source substrate
502 Row line
503 Column line
504 Electron emission element
507 First getter
510 Second getter
511 Reinforcing plate
512 Frame
513 Glass substrate
514 Fluorescent film
515 Metal back
516 Face plate
601 Glass substrate
602 Anode
603 Element separating film
604 Layer related to hole
604a Hole injection layer
604b Hole transport layer
605 Emission layer
606 Electron transport layer
607 Electron injection layer
608 Cathode
610 Mask

### BEST MODE FOR CARRYING OUT THE INVENTION

Hereinafter, an embodiment of the present invention will be described with reference to the drawings. In the embodiment, a deposition processing is shown as an example of the processing according to the present invention; however, the processing according to the present invention is not limited to the deposition processing.

In the present invention, a mask used in a processing apparatus is formed of a magnetic material in a thin film form, and tension is applied to a membranous plane of the mask.

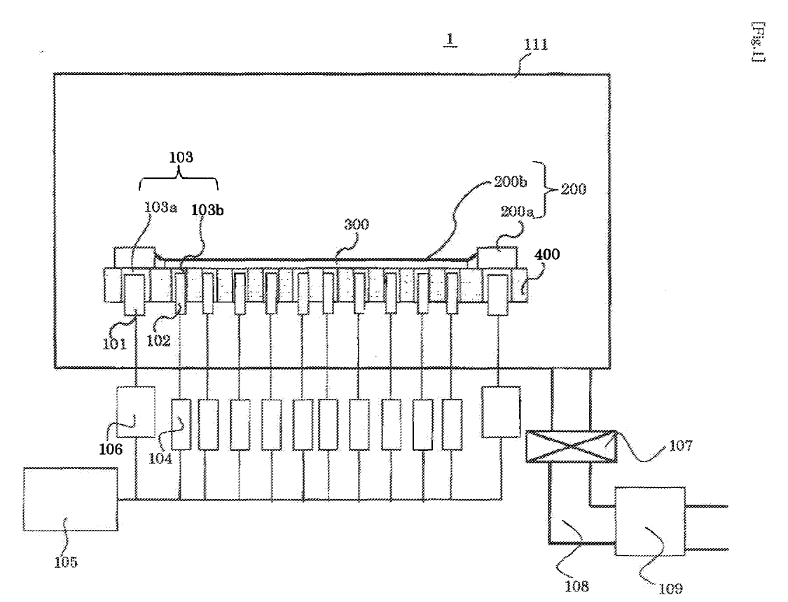

FIG. 1 is a schematic view of a processing apparatus according to the present invention.

FIG. 1 shows a state after the mask fixing operation to be described later. A mask fixing device is turned upside down upon deposition, and deposition is performed in such a state that a mask and the processing surface of a substrate are directed downward.

A processing apparatus 1 includes fixing means (second fixing means) 101 for fixing a mask frame 200a and fixing means (first fixing means) 102 for fixing a mask member (hereinafter also referred to as a “mask membranous plane”) 200b.

The second and first fixing means 101 and 102 move in a base 400 respectively through holes 103a and 103b.

In the present embodiment, a permanent magnet applying a magnetic force to a mask 200, formed of a magnetic material, is used as the second and first fixing means 101 and 102.

The second and first fixing means 101 and 102 will be described in detail. The processing apparatus 1 of FIG. 1 includes a plurality of the first fixing means 102 which can each independently operate.

The processing apparatus further includes a plurality of second fixing means 101 which can each independently operate.

The first fixing means 102 can independently operate without being affected by the operation of the second fixing means 101. The second fixing means 101 also can independently operate without being affected by the operation of the first fixing means 102. Also, the first fixing means 102 can each independently operate.

Next, control means that controls the operation of the first and second fixing means 102 and 101 will be specifically described.

First, the first and second fixing means 102 and 101 are connected respectively to driving mechanisms 109 and 106, which can each independently operate, such as a servo motor, a pulse motor, and a pneumatic driving mechanism using a pressure of air.

Further, the driving mechanism 104 for the first fixing means 102 and the driving mechanism 106 for the second fixing 101 are connected to control means 105 that controls driving of the first and second fixing means 102 and 101.

The driving mechanism 104 for the first fixing means 102 and the driving mechanism 106 for the second fixing means 101 are controlled by the control means 105 as follows.

The individual driving mechanisms 104 connected to the first fixing means 102 can be each independently controlled. Also, control can be performed on the driving mechanisms 104 such that one or more driving mechanisms 104 operate in synchronism with each other.

The individual driving mechanisms 106 connected to the second fixing means 101 can also be each independently controlled.

The individual driving mechanisms 104 connected to the first fixing means 102 can be independently controlled without being affected by the operation of the driving mechanisms 106.

The individual driving mechanisms 106 connected to the second fixing means 101 can also be independently controlled without being affected by the operation of the driving mechanisms 104.

The first and second fixing means 101 and 102 can be operated by the above control method, as described above.

The driving mechanisms 104 and 106 that drive the mask frame 200a and the mask membranous plane 200b are not necessarily controlled by the same control means 105, and they may be controlled by different control means.

The holes 103a and 103b may penetrate through the base 400 having the holes 103a and 103b, or one ends thereof may be sealed with remaining predetermined thickness.

The other components 107 to 109 and 111 will be described as follows.

A gate valve 107 is used for communicating and blocking between the inside of a vessel 111 of the processing apparatus 1 and evacuation means 109. The component 108 is a evacuation tube.

The evacuation means 109 evacuates the inside of the vessel 111 of the processing apparatus 1 and is, for example, a turbomolecular pump, a mechanical booster pump, and a cryopump.

In the processing apparatus shown in FIG. 1, an object to be processed 300, such as a substrate, is conveyed by a conveyance system (not shown) to be placed on the base 400 by means for delivering an object to be processed (not shown). Also, the mask 200 stored at a different place in the same deposition chamber or in a separate chamber in the processing apparatus is conveyed by mask conveying means (not shown) to be disposed on the base 400. The mask 200 is disposed on the base 400 so as to be located above the object to be processed 300.

Thereafter, after the mask fixing operation to be described later, the mask 200 is fixed onto the object to be processed 300 on the base 400, as shown in FIG. 1. The mask 200 which is a mask mechanism is constituted of the mask frame 200a with high rigidity and the thin mask member 200b (hereinafter referred to as a “mask membranous plane”).

The mask 200 is formed of metal, and, for example, an iron-based magnetic material is required to be used in the mask 200. Especially, in order to reduce thermal expansion due to radiation heat input in the deposition, a low thermal expansion material such as an iron-nickel alloy, for example, an invar material is used.

As a desired pattern, small openings are formed on the mask membranous plane 200b, which is a magnetic mask member, by etching or the like. The mask membranous plane is required to reduce the thickness as the pattern accuracy becomes highly fine, and a metal film can be processed to have a thickness of not more than 50 microns.

The mask membranous plane 200b is fixed at its peripheral edges to the mask frame 200a, which is a magnetic mask frame, by welding or the like in such a state that tension is applied to the mask membranous plane 200b.

The mask frame 200a is required to have such rigidity that deformation, occurring due to the reaction force against the tension applied to the mask membranous plane 200b, is not more than a required value as described below. The tension required for maintaining the flatness of the mask membranous plane 200b is determined from properties of matter (elastic coefficient) of a mask material and thermal deformation of the mask itself upon deposition, and the tension of about 2.9 N/m (0.3 kgf/m) is required per unit length. When an analysis is performed by a finite element method, using the value as the calculation condition, the cross-sectional shape of the frame, that is required for the deformation of a 55-inch sized mask frame (inside dimension is 1350 mm×820 mm) to be kept within a range of not more than 50 μm, is required to be a cross section of 125 mm×60 mm, and the weight is 280 kg. Namely, when the mask 200 has the above rigidity, the weight of the entire mask 200 is increased, and a mask, which is used for a substrate having a size of approximately 1300 mm×800 mm, has a weight of 300 kg.

The processing apparatus fixing the mask 200 and the object to be processed 300 includes the base 400 on which the mask 200 and the object to be processed 300 are placed. The base 400 includes the first fixing means 102 and the second fixing means 101. The second fixing means 101 firmly fixes the mask frame 200a of the mask 200 onto the surface of the base 400 on which the mask 200 will be placed. The first fixing means 102 fixes the mask membranous plane 200b onto the placement surface of the base 400. More specifically, the second and first fixing means 101 and 102 are mechanisms that can move a magnet, which is fixing force generation means, close to and away from the placement surface of the base 400, on which the mask 200 and the object to be processed 300 are placed, through a through-hole of the base 400. The processing apparatus further includes a moving mechanism that can move the base 900 so that the processing surface of the object to be processed 300 on the base 400 is directed upward or downward in a vertical direction, and, in addition, can move the base 400 in a direction vertical to the processing surface.

Next, the mask fixing operation in the processing apparatus of the present invention will be described.

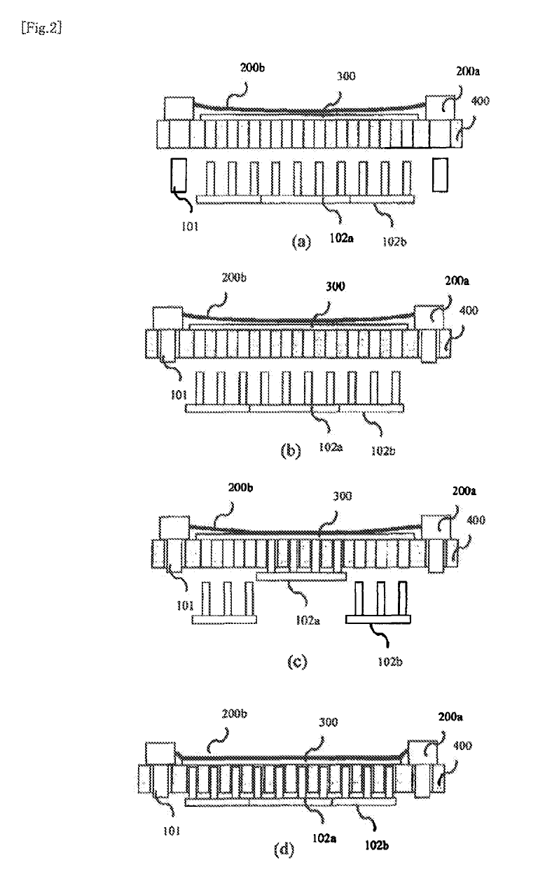

FIG. 2 is a view showing a state from positional alignment of the mask to preparation of the deposition in the processing apparatus of the present invention.

In the processing apparatus shown in FIG. 2, the first fixing means is divided into two independently operable groups 102a and 102b. The first fixing means belonging to the group 102a synchronously operate, and the first fixing means belonging to the group 102b also synchronously operate. More specifically, the group 102a is constituted of a plurality of first fixing means that fix the central portion of the mask membranous plane, and the group 102b is constituted of a plurality of first fixing means that fix the peripheral portion of the mask membranous plane. The first fixing means belonging to the group 102a are connected to each other and configured to synchronously operate. Also, the first fixing means belonging to the group 102b are connected to each other and configured to synchronously operate. The first fixing means belonging to the same group may be configured to synchronously operate, and are not required to be connected to each other.

FIG. 2(a) shows the state where the position of the mask is aligned with the substrate which is the object to be processed 300. The object to be processed 300 is placed on the base 400 in such a state that the processing surface is directed upward, and the mask 200 is placed on the base 400 so as to cover the object to be processed 300 from above. The mask 200 is the large-sized mask for a substrate with a size of 1300 mm×800 mm and is fixed without creases or deflection of the mask membranous plane 200b. However, the mask membranous plane 200b is fixed at only its periphery to the mask frame 200a, and therefore, the mask membranous plane 200b is slightly extended under its own weight as shown in FIG. 2.

In the present embodiment, in order to form a predetermined pattern with high accuracy on the object to be processed 300, the relative position between the mask 200 and the object to be processed 300 in FIG. 2(a) should be determined on the plane of the base 900 so as to fall within a predetermined accuracy range.

In the positional alignment between the mask 200 and the object to be processed 300, the mask 200 and/or the object to be processed 300 is moved by a positional alignment mechanism (not shown), whereby the mask 200 and the object to be processed 300 can be disposed at a predetermined position.

In the relative movement between the mask 200 and the object to be processed 300, if they are in contact with each other, the object to be processed 300 may be damaged. Therefore, as shown in FIG. 2(a), a fixed interval is provided between the mask 200 and the object to be processed 300 so that they are not in contact with each other, whereby the object to be processed 300 is prevented from being damaged.

However, if the interval is large, the large interval causes the positional deviation when the mask membranous plane 200b and the object to be processed 300 are adhered and fixed to each other in the following procedure. Therefore, the interval is preferably as small as possible. Specifically, the upper limit of the interval is preferably not more than 50 μm.

In FIG. 2(b), only the second fixing means 101 for the mask frame 200a are independently operated after the positional alignment of the mask, and the mask frame 200a is firmly fixed to the base 400 by a magnetic force. The second fixing means 101 controls the magnetic fixing force by driving a permanent magnet, which is the fixing force generation means, vertically to the mask placement surface of the base 400 by means of an external driving mechanism (not shown).

In the present embodiment, the permanent magnet is used as the fixing force generation means for the mask frame 200a; however, mechanical fixing means for mechanical fixing using a clamp and an electromagnet may be used.

In FIG. 2(b), only the mask frame 200a is fixed to the base 400, and a predetermined interval is provided between the mask membranous plane 200b and the object to be processed 300. Therefore, the positional deviation caused by the fixing operation may not occur.

In FIG. 2(c), the central portion of the object to be processed 300 and the central portion of the mask membranous plane 200b are in contact with each other after the mask frame 200a is fixed to the base 400.

At that time, only the group 102a including fixing means corresponding to the central portion of the mask membranous plane 200b is independently operated, and the central portion of the mask membranous plane 200b is elastically deformed by the magnetic force, whereby the central portion of the object to be processed 300 and the central portion of the mask membranous plane 200b are in contact with each other.

The fixing means belonging to the group 102a controls the magnetic fixing force by driving a permanent magnet, which is the fixing force generation means, vertically to the mask placement surface of the base 400 by means of an external driving mechanism (not shown).

In the present embodiment, the permanent magnet is used as the fixing force generation means for the central portion of the mask membranous plane 200b; however, the fixing force generation means is not limited to the permanent magnet, and any means that can generate the fixing force can be used.

Since the central portion of the mask membranous plane 200b is first in contact with the object to be processed 300, a good adherence with the processing surface of the object to be processed 300 can be ensured without causing creases of the mask membranous plane and the positional deviation occurring when the entire mask membranous plane is fixed to the object to be processed.

In FIG. 2(d), the object to be processed 300 and the mask membranous plane 200b are completely in surface contact with each other after the central portion of the object to be processed 300 and the central portion of the mask membranous plane 200b are in contact with each other. At that time, only the group 102b including fixing means corresponding to the peripheral portion of the mask membranous plane 200b is independently operated, and the entire mask membranous plane 200b is elastically deformed in the direction of the processing surface of the object to be processed 300, whereby the mask membranous plane 200b and the object to be processed 300 are completely in surface contact with each other.

When a magnet as the fixing force generation means is used in the fixing means belonging to the groups 102a and 102b, each magnet is disposed so that the magnetic fixing force that firmly fixes the mask membranous plane 200b to the processing surface of the object to be processed 300 is uniformly exercised. Specifically, the magnets are uniformly arranged in a plane facing the processing surface, whereby the magnetic fixing force can be uniformly exercised.

In the present embodiment, the external driving mechanism (not shown) drives the permanent magnet, which is the fixing force generation means, vertically to the mask placement surface, whereby the magnetic fixing force for the mask is controlled. However, also when the fixing means is constituted so that the fixing force for the mask membranous plane can be changed for each area in the mask membranous plane without providing the driving mechanism for the fixing force generation means, the mask fixing operation can be realized.

Thus, the method of controlling the fixing force is not limited to the driving system shown in FIG. 2 when the fixing force can be changed in the central portion and the peripheral edge of the mask membranous plane 200b. Thus, the kind of the magnetic is not limited to the permanent magnet, and an electromagnet whose magnetic force can be electrically controlled may be used.

When the sequential operation shown in FIGS. 2(a) to 2(d) is terminated, the mask membranous plane 200b and the processing surface of the object to be processed 300 are tightly adhered to each other by the magnetic fixing force. At that time, the object to be processed 300 is held and fixed by being sandwiched between the mask membranous plane 200b and the base 400.

The above constitution can realize the function of fixing the object to be processed 300 to the base 400 even if the object to be processed 300 is a non-magnetic body such as a glass substrate.

A glass substrate is widely used as a substrate for a flat panel display. For this purpose, in the prior art processing apparatus, an instrument such as an electrostatic chuck is provided on the base 400, whereby the function of fixing the glass substrate is ensured. On the other hand, according to the present invention, since the object to be processed 300 can be held and fixed by the force that fixes the mask membranous plane 200b toward the base 400 side, the object to be processed 300 which is a non-magnetic body can be fixed without using the electrostatic chuck, resulting in a significant contribution to the reduction of the apparatus cost.

The mask fixing procedure described with reference to FIGS. 2(a) to 2(d) can be easily programmed. Therefore, the mask fixing procedure is described in the operation program of the apparatus, whereby the mask fixing can be easily automated, resulting in a significant contribution to the power saving of the apparatus.

When the positional alignment and fixing of the object to be processed 300 and the mask 200 on the base 400 are completed as described above, the base 400 having the fixing means 101 and 102 is turned upside down by a moving mechanism (not shown) so that the processing surface is directed downward. The base 400 having the fixing means 101 and 102 is disposed above a deposition source in a vacuum chamber (not shown) while the processing surface is directed downward (faced down), and a film-formation material is formed in a desired pattern on the processing surface through the mask 200.

In the collection of the object to be processed 300, the base 400 is turned upside down by a moving mechanism (not shown). Subsequently, the mask 200 is transferred to a different place in the same deposition chamber or in a separate chamber in the processing apparatus by mask conveying means (not shown). Further, a conveyance system receives the object to be processed 300 from means for delivering an object to be processed (not shown), and the object to be processed 300 is carried to a predetermined position to be collected.

Although the present embodiment is an application example related to the vacuum deposition apparatus, the mask fixing method according to the present invention can be used in not only the film-formation method but also a sputtering method.

Next, a preferred embodiment of the present invention will be described.

In order to endure highly fine pattern accuracy even when an object to be processed is increased in size, two significantly different designs are required for the mask fixing means. One of the designs is to fix a mask significantly increased in weight, and another of that to ensure the adhesion between the mask and the object to be processed.

Thus, the fixing and releasing of the fixing of the mask frame accounting for the majority of the weight of the mask and the fixing and releasing of the fixing of the mask membranous plane requiring adherence with the object to be processed can be respectively performed by separate fixing means. According to this constitution, the mask positional alignment operation can be performed without adhering and fixing the mask membranous plane to the processing surface. Consequently, there can be realized such an operation that prevents the occurrence of a damage caused by the contact between the mask and the object to be processed and positional deviation caused by impact.

According to the above constitution, the film formation can be performed while maintaining such a state that the position of the mask is precisely aligned. Further, the positional alignment of the mask and the film formation can be performed without dividing the processing area into ranges capable of ensuring the accuracy, unlike the technique disclosed in Patent Document 4, whereby it is possible to realize highly accurate film formation processing that can correspond to the increase of the size of the object to be processed.

In the present invention, it is preferable that the mask frame is disposed so as to be prevented from being directly in contact with the object to be processed. According to this constitution, even when only the mask frame is fixed to the base after the positional alignment of the mask, an interval can be provided between the object to be processed and the mask, and consequently, there can be realized such an operation that prevents the occurrence of positional deviation caused by impact and contact damage. Therefore, the film formation can be preformed while maintaining such a state that the position of the mask is precisely aligned.

In the fixing means 101 for the mask frame, it is preferable that the fixing force generation means for the mask frame 200a exercises the fixing force, larger than gravity of the entire mask, in the vertical direction with respect to the mask placement surface of the base. When the processing surface of the object to be processed is tilted, it is preferable that the fixing force of the fixing force generation means for the mask frame is set so that the frictional force of the mask frame in a direction parallel to the mask placement surface is larger than a component of the gravity of the entire mask, that is parallel to the mask placement surface. The fixing force for the mask frame accounting for the majority of the weight of the mask is determined by considering not only the gravity of the entire mask but also the frictional force against the placement surface generated in the movement of the mask. According to this constitution, it is possible to maintain such a state that the position of the mask is precisely aligned even when the mask is put in the face down attitude in the film formation, and, at the same time, the movement of the mask and the accidental falling can be prevented.

In the fixing means 102 for the mask membranous plane, it is preferable that the fixing force generation means for the mask membranous plane exercises the fixing force, that is larger than the sum of the gravity of the mask membranous plane and the gravity of the object to be processed in contact with the mask membranous plane, in the vertical direction with respect to the base. Further, when the processing surface of the object to be processed is tilted, it is preferable that the fixing force of the fixing force generation means for the mask frame is set so that the following frictional force is exercised. Namely, the fixing force is set so that the frictional force between the base and the object to be processed is larger than a component of the sum of the gravity of the object to be processed and the gravity of the mask membranous plane, that is parallel to the base, and, at the same time, so that the frictional force between the object to be processed and the mask membranous plane is larger than a component of the gravity of the mask membranous plane, that is parallel to the processing surface of the object to be processed.

As described above, the fixing force for the mask membranous plane is determined by considering not only the gravity of the mask membranous plane and the object to be processed but also the frictional force between the mask membranous plane and the object to be processed generated in the movement of the mask. According to this constitution, when the object to be processed is moved to be put in the face down attitude in the film formation, the adhesion between the object to be processed and the mask and the resting state can be maintained. Thus, the positional deviation of the mask can be prevented, and the film formation can be performed while maintaining such a state that the position of the mask is precisely aligned. Further, even when the object to be processed is put in the face down attitude during deposition, the adhesion between the object to be processed and the mask can be maintained, and, at the same time, falling of the object to be processed can be prevented, whereby the film formation can be performed while maintaining such a state that the position of the mask is precisely aligned.

Furthermore, the object to be processed itself is fixed onto the base through the mask membranous plane, and therefore, it is possible to obtain, without using an electrostatic chuck, the same effects and functions as those in the case of using an electrostatic chuck in the mechanism that fixes the object to be processed. Consequently, it is possible to realize the cost reduction of the processing apparatus due to the simplification of the mask fixing means and the tact up of the apparatus due to the reduction in the time required for preparing to fix the mask, whereby a productive apparatus can be realized.

In the fixing means for the mask membranous plane, it is preferable that magnetism for fixing the mask membranous plane are arranged so that the magnetic force is uniformly distributed on the contact surface between the mask and the object to be processed. This constitution can enhance the adhesion between the object to be processed and the mask and bring the mask membranous plane into contact with the processing surface without causing positional deviation or creases. Thus, the film formation can be performed while maintaining a good adhesion state between the object to be processed and the mask.

While the positions of the mask and the object to be processed are aligned, it is preferable that the mask is fixed so that a constant minute interval is provided between the mask membranous plane and the processing surface of the object to be processed. According to this constitution, the planar movement for the mask positional alignment can be performed without causing contact between the mask and the object to be processed during the relative movement of the mask and the object to be processed. Consequently, the positional deviation between the mask and the object to be processed caused by impact and contact damage of the object to be processed can be prevented from occurring in the mask positional alignment.

In the fixing of the mask membranous plane, it is preferable that the fixing force is applied to the mask membranous plane so that the mask membranous plane is fixed from the central portion of the object to be processed toward the peripheral edge.

Although tension is applied to the mask membranous plane, the mask membranous plane is slightly extended by its own weight (see, FIG. 2). Since the extension deformation includes multiple error elements including processing accuracy and flatness, it cannot be controlled. Thus, when the contact of the mask membranous plane with the object to be processed is started from an arbitrary small area or portion, the mask membranous plane is not always favorably adhered to the object to be processed so as to follow the processing surface of the object to be processed.

Thus, in the present invention, the mask membranous plane is brought into contact with the object to be processed in sequence from the central portion of the object to be processed toward the peripheral edge. Consequently, good adhesion can be ensured without causing creases of the mask and the positional deviation of the mask from the object to be processed.

Comparing with a method disclosed in Patent Document 6, in which the mask is adhered in sequence from one end of the object to be processed, the mask fixing procedure of the present invention can be easily extended to the case of increasing the sizes of the mask and the object to be processed.

The reason comes from the fact that the mask membranous plane can be adhered to the object to be processed, in a centrally symmetric manner, from the central portion of the object to be processed toward the peripheral edge, and therefore, if creases occur in the mask, the distance moved by the creases to the outside of the peripheral edge of the object to be processed is always the shortest. Namely, it is estimated that in the fixing of the mask, when the deviated mask cannot be deformed so as to follow the object to be processed, the deviation is remained, whereby creases occur in the mask. Even when creases occur, if the deformation is moved as it is to the end of the object to be processed, the creases are eliminated. However, the longer the distance from the location of the occurrence of creases to the peripheral edge of the object to be processed, the higher the possibility that deformation such as creases is left. Thus, in the prior art method of fixing the mask in sequence from one end of the object to be processed, the distance moved by the deformed portion of the mask, such as creases, to the outside of the peripheral edge of the object to be processed may be elongated in one direction. Namely, in the prior art method, when the sizes of the mask and the object to be processed are increased, it is difficult to maintain a good mask adhesion state free from creases and the like.

On the other hand, according to the mask fixing procedure of the present invention, since the distance that allows deformation such as creases to release can be minimized, the mask fixing procedure can be easily extended to the case of increasing the sizes of the mask and the object to be processed.

Further, the mask and the object to be processed can be easily adhered to each other in sequence from the center of the object to be processed to the peripheral edge by controlling the fixing force of the mask. There can be used a variety of methods which suit the properties of the apparatus, such as the movement of the permanent magnet close to and away from the mask membranous plane and the disposition of the permanent magnet that allows the fixing force to be changed in an area corresponding to the mask membranous plane, or ON/OFF control by means of an electromagnet.

In the mask fixing procedure after the position alignment between the mask and the object to be processed, it is preferable that the mask frame is first fixed, and the mask membranous plane is then fixed. In the procedure for fixing the mask membranous plane, it is preferable that the mask membranous plane is brought into contact with the object to be processed in sequence from the center of the object to be processed toward the peripheral edge.

In the present invention, since the fixing force required for the fixing means is proportional to the weight of a fixed object, the fixing force required for the mask frame is significantly larger than that for the mask membranous plane.

The mask frame requiring a larger fixing force is first fixed, and the mask membranous plane is then fixed, whereby the object to be processed can be fixed and held by only the elastic deformation of the mask membranous plane without causing the positional deviation of the mask.

According to the above constitution, the film formation can be performed without causing damage caused by the contact between the mask and the object to be processed and positional deviation caused by impact.

The operation procedure of the fixing means according to the present invention can be easily realized in an operation control sequence of the processing apparatus. The operation procedure is automated by a program, for example, whereby the operation can be eased, and the reliability of the apparatus can be further enhanced.

Hereinafter, an example of the application of the processing apparatus will be described.

First, an example in which the processing apparatus is used in an electron emission element display is shown.

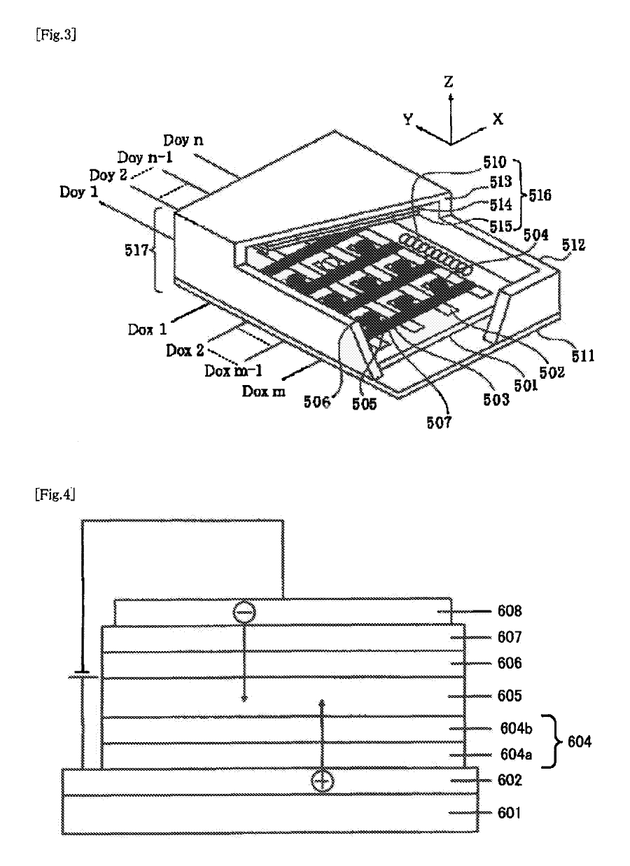

FIG. 3 is a perspective view of an electron emission element display which is manufactured by using the processing apparatus according to the present invention and is one of image display apparatuses.

The electron emission element display includes an electron source substrate 501, row lines 502, column lines 503, electron emission elements 504, a first getter 507, and a second getter 510.

The electron emission element display further includes a reinforcing plate 511, a frame 512, a glass substrate 513, a fluorescent film 514, a metal back 515, column selection terminals Dox1 to Doxm, and row selection terminals Doy1 to Doyn. The glass substrate 513, the fluorescent film 514, and the metal back 515 constitute a face plate 516.

In the electron emission element display, the electron emission element 504 is disposed at a position where the row line 502 and the column line 503 intersect with each other on a plane. When a predetermined voltage is applied to the selected row line 502 and the selected column line 503, electrons are emitted from the electron emission element 504 located at the position where the row line 502 and the column line 503 intersect with each other on a plane, and the electrons are accelerated toward the face plate 516 subjected to a positive high voltage. The electrons collide against the metal back 515 to excite the fluorescent film 514 in contact with the metal back 515, and thus the fluorescent film 514 emits light.

A space surrounded by the face plate 516, the frame 512, and the glass substrate 513 is maintained in vacuum. In order to maintain the space in a vacuum state over the life of the image display apparatus, a getter material is disposed in the space. As the getter material, there are an evaporating getter and a non-evaporating getter, and they are appropriately used. As the evaporating getter, there has been known a single metal such as Ba, Li, Al, Hf, Nb, Ta, Th, Mo, and V or alloy thereof. As the non-evaporating getter, there has been known a single metal such as Zr and Ti or alloy thereof. The evaporating getter and the non-evaporating getter are made of metal and are conductive materials.

In the example of FIG. 3, the first getter 507 is formed on the column line 503. In the formation of the first getter 507, the electron source substrate 501 on which the column line 503 and the components under the column line 503 are produced is placed on a holder of the processing apparatus of the present invention. The position of a metal mask having the shape of the column line 503 is aligned, and then the metal mask is located on the electron source substrate 501. Thereafter, the first getter 507 is film-formed by a vacuum deposition method, a sputtering method, or a chemical vapor deposition method, for example. The thickness of the first getter 507 is approximately 2 μm.

In the production of the first getter, since an electroconductive film, which will finally become the electron emission element 504, is already formed, it is crucial to produce the first getter without the first getter electrically conducting with the electroconductive film. The allowable error of the positional alignment at that time is approximately ±3 μm.

Meanwhile, it is considered that the image display apparatus is getting larger and larger and have higher definition, and consequently the allowable error of the positional alignment is getting smaller and smaller.

Thus, the processing apparatus of the present invention, which can realize the highly accurate positional alignment of a large and heavy mask, is suited particularly for use in the manufacturing of the electron emission element display.

Next, an example of the application of an organic light-emitting display (hereinafter referred to as “organic EL display”) is shown.

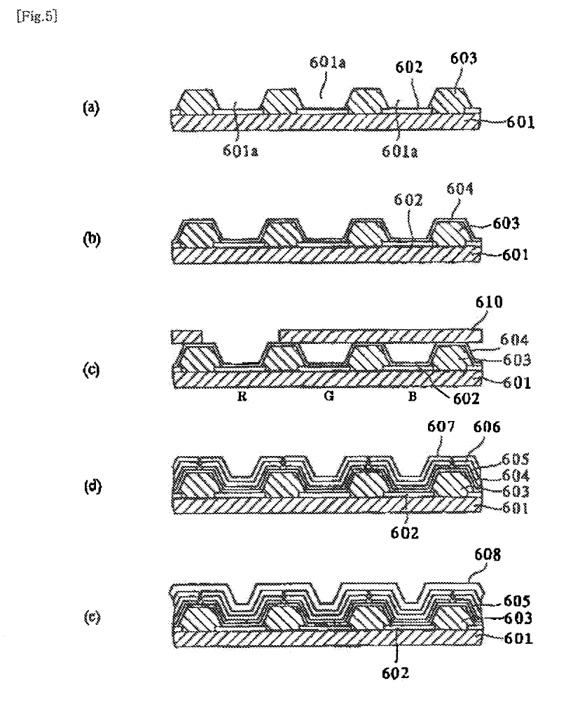

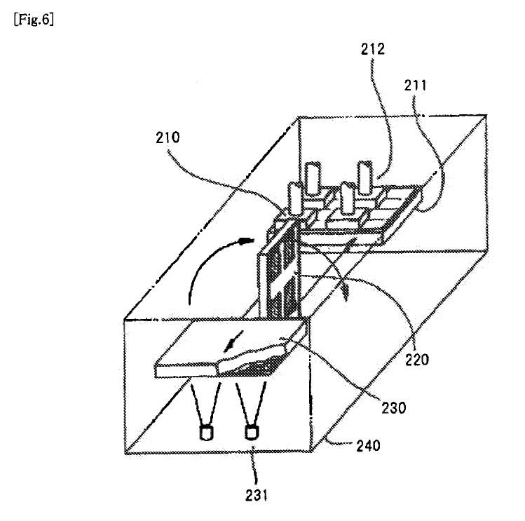

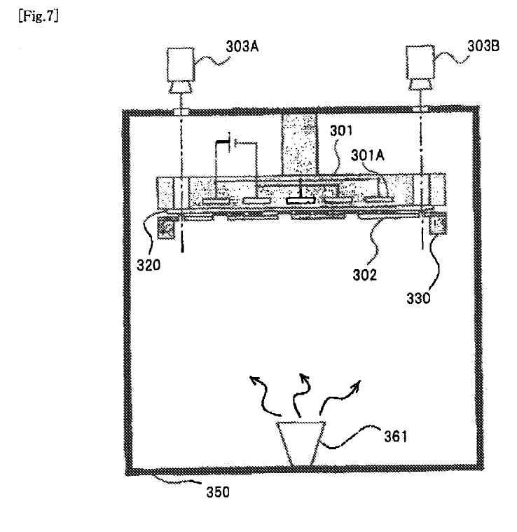

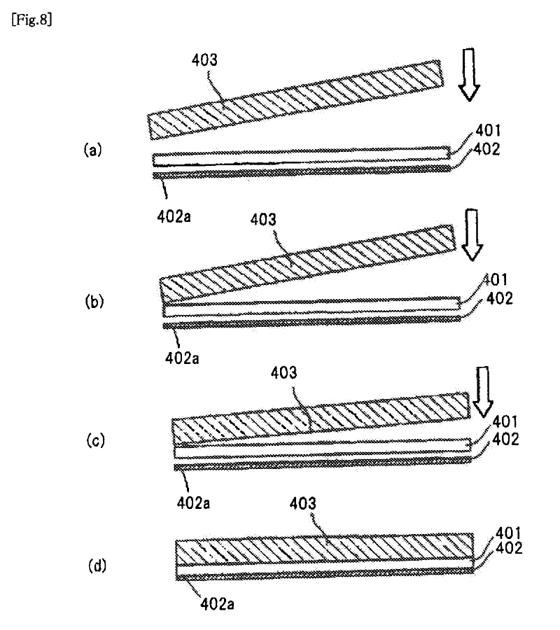

FIG. 4 is a schematic view of a structure of an organic EL display which is one of image display apparatuses particularly suited to be manufactured by using the processing apparatus according to the present invention.

The organic light-emitting display includes a glass substrate 601, an anode 602, a layer 604 related to a hole, an emission layer 605, an electron transport layer 606, an electron injection layer 607, and a cathode 608. The layer 604 includes a hole injection layer 604a and a hole transport layer 604b.

In the operation of the organic EL display, when a voltage is applied to between the anode 602 and the cathode 608, holes are injected into the hole transport layer 604a from the anode 602. Meanwhile, electrons are injected into the electron injection layer 607 from the cathode 608. The injected holes move through the hole transport layer 604a and the hole transport layer 604b to reach the emission layer 605, and the injected electrons move through the electron injection layer 607 and the electron transport layer 606 to reach the emission layer 605. The holes and electrons having reached the emission layer 605 are recombined to emit light.

The material of the emission layer 605 is suitably selected, whereby red, green, and blue lights which are light's three primary colors can be emitted, and consequently a full-color image display apparatus can be realized.

Next, the production of the light-emitting part will be described with reference to FIG. 5. In FIG. 5, one pixel including portions emitting lights of red, green, and blue (R, G, and B) will be described. FIG. 5 is a flow chart showing a general method of manufacturing the light-emitting part of the organic EL display. First, a high reflectance electroconductive film is formed on the substrate 601 such as a glass substrate. In the previous process, a Thin Film Transistor (hereinafter referred to as “TFT”) and a wiring part are fabricated on the substrate 601, and thereafter the film-formation processing for planarization is applied to the substrate 601. The electroconductive film is patterned into a predetermined shape, whereby the anode electrode 602 is formed. Next, an element separating film 603 constituted of a highly insulating material is formed so as to surround the portions emitting lights of R, G, and B on the anode electrode 602.

According to the above constitution, the element separating film 603 partitions between the adjacent light emitting portions R, G, and B. Then, the layer 604 (actually formed of the hole transport layer 604a and the hole transport layer 604b) related to a hole, the emission layer 605, the electron transport layer 606, and the electron injection layer 607 are produced sequentially on the anode electrode 602 by a deposition method. The cathode electrode 608 formed of a transparent electroconductive film is stacked on the electron injection layer 607, whereby a light emitting part of the organic EL display is formed on the substrate 601.

Finally, the light emitting part on the substrate is covered by a sealing layer (not shown) formed of a low permeable material.

When the R, G, and B emission layers 605 are produced by a deposition method, the green and blue light emitting portions G and B are covered by a mask 610 as shown in FIG. 5C. In FIG. 5C, the red light emitting portion R is produced.

Thus, the green and blue light emitting portions G and B are covered by the mask 610 so that the red light emitting material is prevented from being mixed in the green and blue light emitting portions G and B. The mask 610 is used in a similar manner for the green and blue light emitting portions G and B.

For example, in a full color organic EL display with a diagonal size of 5.2 inches and 320×240 pixels, the pixel pitch is 0.33 mm (330 μm), and the subpixel pitch is 0.11 mm (110 μm). In such a display, the alignment accuracy of a mask is required to be not more than several microns.

Also in the production of the hole transport layer 604b, the emission layer 605, the electron transport layer 606, and the electron injection layer 607, they are produced in different chambers in order to prevent the mixing of each organic material, and a dedicated mask is used for each layer.

Thus, also in the film-formation process for the above layers, each mask is required to be aligned at the same position with high accuracy.

Thus, highly accurate and rapid mask alignment is necessary for the improvement of the productivity and yield of the organic EL display.

It is considered that the demand for a display having a large display screen is increased more and more, whereby it is predicted that the demand for the highly accurate and rapid alignment of a heavy large mask is increased more and more.

Thus, the processing apparatus of the present invention, which can realize the highly accurate and rapid alignment of a heavy large mask is suited particularly for use in the manufacturing of the organic EL display.

1. A processing apparatus, which processes an object to be processed by using a mask mechanism having a magnetic mask member and a magnetic mask frame fixing the periphery of the magnetic mask member, and the magnetic mask member comprising:
a plurality of first fixing means which fix the magnetic mask member and can each independently operate; and
second fixing means which operates independently from the first fixing means and fixes the magnetic mask frame.

2. The processing apparatus according to claim 1, wherein the plurality of first fixing means are divided into a plurality of independently movable groups.

3. The processing apparatus according to claim 1, wherein the magnetic mask member is provided so as to form an interval with a processing surface of the object to be processed before being adhered and fixed to the processing surface.

4. The processing apparatus according to claim 3, wherein the interval is not more than 50 μm.

5. The processing apparatus according to claim 1, wherein the first and second fixing means comprise a member generating a magnetic force.

6. The processing apparatus according to claim 1, wherein the second fixing means uses a mechanism that mechanically fixes the magnetic mask frame.

7. The processing apparatus according to claim 1, wherein when the magnetic mask member is fixed, the first fixing means applies a magnetic force to the magnetic mask member so that the magnetic mask member is fixed from the center portion of the object to be processed toward the peripheral edge.

8. A method of manufacturing an electron emission element display comprising a step of processing an object to be processed by using the processing apparatus according to claim 1.

9. A method of manufacturing an organic EL display comprising a step of processing an object to be processed by using the processing apparatus according to claim 1.
